(19) United States
(12) Patent Application Publication
(10) Pub. No.: US 2014/0284302 A1
(43) Pub. Date: Sep. 25, 2014

(54) METHOD FOR MANUFACTURING LIQUID EJECTING HEAD, METHOD FOR MANUFACTURING PIEZOELECTRIC ELEMENT, METHOD FOR PATTERNING PIEZOELECTRIC FILM, AND METHOD FOR MANUFACTURING ULTRASONIC TRANSDUCER

(71) Applicant: SEIKO EPSON CORPORATION, Tokyo (JP)

(72) Inventor: Hideki HAHIRO, Yamagata-mura (JP)

(73) Assignee: SEIKO EPSON CORPORATION, Tokyo (JP)

(21) Appl. No.: 14/179,323

(22) Filed: Feb. 12, 2014

(30) Foreign Application Priority Data
Mar. 22, 2013 (JP) 2013-060904

(51) Int. Cl. H01L 41/332; B41J 2/16

(52) U.S. Cl. CPC H01L 41/332; B41J 2/1607
USPC 216/13

(57) ABSTRACT

Provided is a method for manufacturing a liquid ejecting head having a flow path formation substrate that is provided with a liquid flow path communicating with a nozzle opening for discharging liquid and a piezoelectric element that is provided on the flow path formation substrate and applies pressure to the liquid flow path. The method includes forming a piezoelectric film for the piezoelectric element containing a perovskite oxide which does not contain lead and patterning the piezoelectric film by applying a resist on the piezoelectric film and wet etching the piezoelectric film with an etching solution containing either hydrochloric acid or hydrofluoric acid.

### BACKGROUND

1. Technical Field

The present invention relates to a method for manufacturing a liquid ejecting head, a method for manufacturing a piezoelectric element, a method for patterning a piezoelectric film, and a method for manufacturing an ultrasonic transducer.

2. Related Art

Heretofore, a liquid ejecting head which ejects liquid droplets from nozzles communicating with pressure generating chambers by deforming piezoelectric elements to cause pressure fluctuation in liquid in the pressure generating chambers is known. As a typical example thereof, an ink jet recording head which ejects ink droplets as liquid droplets is mentioned.

The ink jet recording head has piezoelectric elements on a surface of a flow path formation substrate provided with pressure generating chambers communicating with nozzle openings, in which diaphragms are deformed by the drive of the piezoelectric elements to cause pressure fluctuation in the pressure generating chambers to thereby eject ink droplets from nozzles, for example.

Such a piezoelectric element contains a first electrode, a piezoelectric layer, and a second electrode provided on the diaphragm. When forming the piezoelectric element, it is known to laminate a piezoelectric film on the second electrode in such a manner as to have a predetermined thickness, and then remove the same by dry etching in such a manner as to have a predetermined shape to thereby form the piezoelectric layer (for example, JP-A-2008-053395, FIG. 6 Paragraph [0056], etc.).

When removing the piezoelectric film by dry etching as described above, there is a problem in that the etching takes time, so that the manufacturing time of the piezoelectric element is prolonged.

In particular, in recent years, it has been required to form a piezoelectric film containing a perovskite oxide which does not contain lead for the safety of operators and the environmental consideration. However, in the case of such a perovskite oxide which does not contain lead, the dry etching takes time particularly in the etching. As a result, there is a problem in that the manufacturing time of the piezoelectric element is prolonged, so that an improvement of the throughput is difficult to achieve.

Moreover, when removing the piezoelectric film by dry etching, there have been problems in that the base layer is damaged due to over etching and the in-plane uniformity of the dry etching depends on an etching system, so that it is difficult to achieve uniformity.

Such problems are not limited to the method for manufacturing an ink jet recording head and similarly arise in methods for manufacturing a liquid ejecting head which ejects liquid other than ink, a piezoelectric film, a piezoelectric element employing the same, and an ultrasonic transducer employing the same.

### SUMMARY

An advantage of some aspects of the invention is to provide a method for manufacturing a liquid ejecting head, a method for manufacturing a piezoelectric element, a method for patterning a piezoelectric film, and a method for manufacturing an ultrasonic transducer, capable of easily etching a piezoelectric layer containing a perovskite oxide which does not contain lead.

A method according to a first aspect of the invention is a method for manufacturing a liquid ejecting head having a flow path formation substrate that is provided with a liquid flow path communicating with a nozzle opening for discharging liquid and a piezoelectric element that is provided on the flow path formation substrate and applies pressure to the liquid flow path, and the method includes forming a piezoelectric film for the piezoelectric element containing a perovskite oxide which does not contain lead and patterning the piezoelectric film by applying a resist on the piezoelectric film and wet etching the piezoelectric film with an etching solution containing either hydrochloric acid or hydrofluoric acid. In an aspect of the invention, the use of the etching solution containing either hydrochloric acid or hydrofluoric acid allows easy patterning of a piezoelectric layer containing a perovskite oxide which does not contain lead by wet etching.

It is preferable that the patterning include a first etching with an etching solution containing either hydrochloric acid or hydrofluoric acid and a second etching with an etching solution containing hydrochloric acid or nitric acid and being different from that of the first etching. By performing the patterning in the two etchings described above, even when a reaction product is generated due to the wet etching, the reaction product can be removed, so that a piezoelectric layer containing a perovskite oxide which does not contain lead can be easily patterned by wet etching.

It is preferable that the second etching be performed after performing the first etching.

It is preferable that the etching solution in the first etching contain hydrofluoric acid and a taper angle of the piezoelectric element be controlled by adjusting a wet etching time in the first etching. When the etching solution in the first etching contains hydrofluoric acid, the taper angle of the piezoelectric element can be controlled by adjusting the wet etching time in this first etching. Then, by adjusting the wet etching time in the first etching to control the taper angle of the piezoelectric element, the inclination of an end portion of the piezoelectric element can be altered to realize desired properties, for example, when the second electrode is a common electrode, the inclination of the end portion thereof is preferably gentle and when the piezoelectric elements are disposed with high density, the inclination of the end portion thereof is preferably steep.

It is preferable that the perovskite oxide which does not contain lead be bismuth ferrite.

It is preferable that the resist contain novolac resin.

According to a second aspect of the invention, a method for manufacturing a piezoelectric element that has a piezoelectric film containing a perovskite oxide which does not contain lead and has a first electrode and a second electrode provided on respective surfaces of the piezoelectric film, includes forming the piezoelectric film, and patterning the piezoelectric film by applying a resist on the piezoelectric film and wet etching the piezoelectric film with an etching solution containing either hydrochloric acid or hydrofluoric acid. The use of the etching solution containing either hydrochloric acid or hydrofluoric acid allows easy patterning of the piezoelectric layer containing a perovskite oxide which does not contain lead by wet etching.

According to a third aspect of the invention, a method for patterning a piezoelectric film includes applying a resist on a piezoelectric film containing a perovskite oxide which does not contain lead, and wet etching the piezoelectric film with an etching solution containing either hydrochloric acid or hydrofluoric acid. The use of the etching solution containing either hydrochloric acid or hydrofluoric acid allows easy patterning of the piezoelectric layer containing a perovskite oxide which does not contain lead by wet etching.

According to a fourth aspect of the invention, a method for manufacturing an ultrasonic transducer that has a piezoelectric film containing a perovskite oxide which does not contain lead and has a first electrode and a second electrode provided on respective surfaces of the piezoelectric film, includes forming the piezoelectric film, and patterning the piezoelectric film by applying a resist on the piezoelectric film and wet etching the piezoelectric film with an etching solution containing either hydrochloric acid or hydrofluoric acid. The use of the etching solution containing either hydrochloric acid or hydrofluoric acid allows easy patterning of the piezoelectric layer containing a perovskite oxide which does not contain lead by wet etching.

### BRIEF DESCRIPTION OF THE DRAWINGS

The invention will be described with reference to the accompanying drawings, wherein like numbers reference like elements.

FIG. 1 is an exploded perspective view of an ink jet recording head according to Embodiment 1.

FIG. 2A is a plan view of the ink jet recording head according to Embodiment 1.

FIG. 2B is a cross sectional view of the ink jet recording head according to Embodiment 1.

FIGS. 3A to 3C are cross sectional views illustrating a method for manufacturing a recording head according to Embodiment 1.

FIGS. 4A to 4C are cross sectional views illustrating the method for manufacturing the recording head according to Embodiment 1.

FIGS. 5A to 5C are cross sectional views illustrating the method for manufacturing the recording head according to Embodiment 1.

FIGS. 6A and 6B are SEM photographs in a manufacturing process of the recording head according to Embodiment 1.

FIGS. 7A to 7C are cross sectional views illustrating the method for manufacturing the recording head according to Embodiment 1.

FIGS. 8A and 8B are SEM photographs in a manufacturing process of a recording head according to Embodiment 2.

FIG. 9 is a schematic view illustrating a liquid ejecting apparatus according to Embodiment 1.

FIGS. 10A and 10B are views illustrating ultrasonic transducers and an ultrasonic device carrying the ultrasonic transducers.

### DESCRIPTION OF EXEMPLARY EMBODIMENTS

Hereinafter, embodiments of the invention are described in detail with reference to the drawings.

### Embodiment 1

### Ink Jet Recording Head

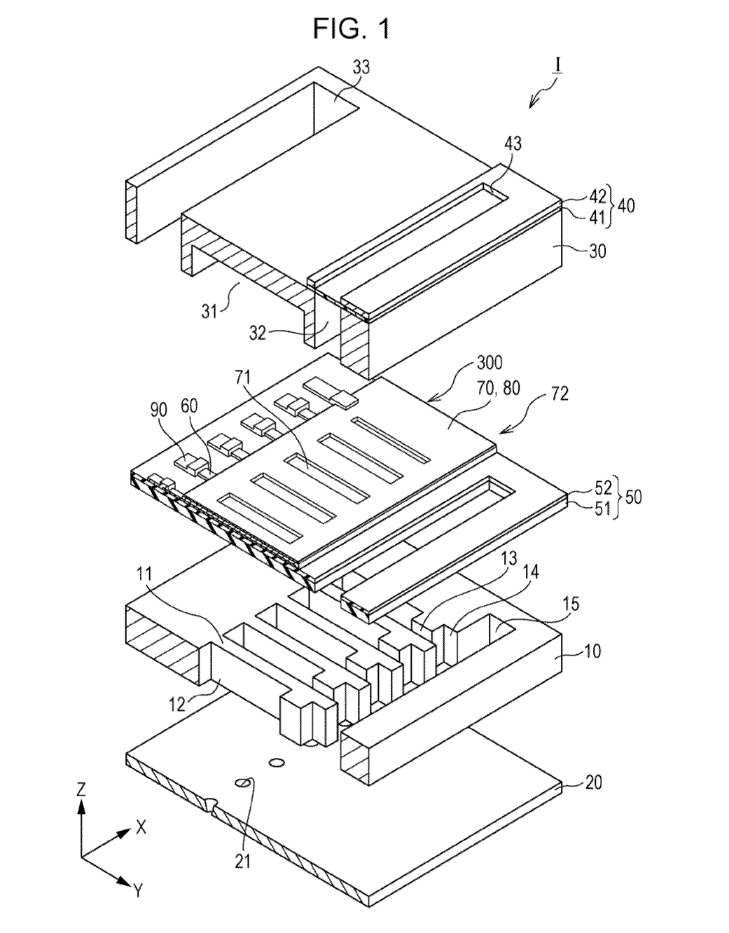

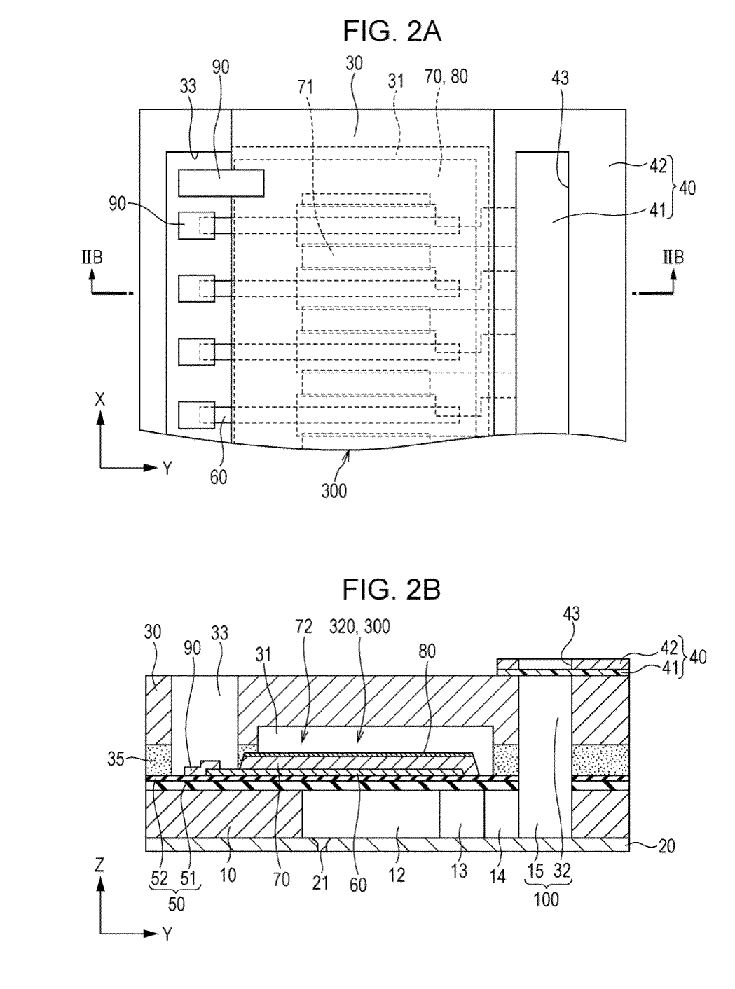

FIG. 1 is a perspective view of an ink jet recording head which is an example of a liquid ejecting head according to Embodiment 1 of the invention. FIGS. 2A and 2B are a plan view and a cross sectional view of the ink jet recording head, respectively.

As illustrated therein, pressure generating chambers 12 are formed in a flow path formation substrate 10 of an ink jet recording head I which is an example of the liquid ejecting head of this embodiment. The pressure generating chambers 12 partitioned by a plurality of partitions 11 are disposed side by side along the direction in which a plurality of nozzle openings 21 which discharge ink are disposed side by side. Hereinafter, this direction is referred to a juxtaposing direction or a first direction X of the pressure generating chambers 12. In the plane of the flow path formation substrate 10, a direction orthogonal to the first direction X is referred to as a second direction Y. A direction orthogonal to the first direction X and the second direction Y is referred to as a third direction Z. In the drawing, the sequence of the pressure generating chambers 12 disposed side by side in the first direction X is illustrated in a single row but the sequence of the pressure generating chambers 12 may be disposed side by side in a plurality of rows in the second direction Y. At one end in the longitudinal direction of the pressure generating chamber 12 of the flow path formation substrate 10, i.e., one end in the second direction Y, an ink supply path 13 and a communication path 14 are partitioned by the plurality of partitions 11. In the outside (side opposite to the pressure generating chambers 12 in the second direction Y) of the communication paths 14, a communication portion 15 constituting part of a manifold 100 serving as a common ink chamber (liquid chamber) of the respective pressure generating chambers 12 is formed. More specifically, the flow path formation substrate 10 is provided with a liquid flow path containing the pressure generating chamber 12, the ink supply path 13, the communication path 14, and the communication portion 15.

To one surface of the flow path formation substrate 10, i.e., surface in which the liquid flow path, such as the pressure generating chamber 12, opens, a nozzle plate 20 in which nozzle openings 21 communicating with the respective pressure generating chambers 12 are formed is bonded with an adhesive, a thermal fusion bonding film, or the like. More specifically, the nozzle openings 21 are disposed side by side in the first direction X in the nozzle plate 20.

On the other surface of the flow path formation substrate 10, a diaphragm 50 is formed. The diaphragm 50 according to this embodiment is constituted by an elastic film 51 formed on the flow path formation substrate 10 and an insulator film 52 formed on the elastic film 51. The liquid flow path, such as the pressure generating chamber 12, is formed by anisotropically etching the flow path formation substrate 10 from one surface and the other surface of the liquid flow path, such as the pressure generating chamber 12, is constituted by the diaphragms 50 (elastic film 51).

On the insulator film 52, a piezoelectric element 300 constituted by a first electrode 60 with a thickness of about 0.2 μm, a piezoelectric layer 70 with a thickness of about 1.0 μm, and a second electrode 80 with a thickness of about 0.05 μm is formed. The piezoelectric element 300 provided on this substrate (flow path formation substrate 10) functions as an actuator device in this embodiment.

Hereinafter, the piezoelectric element 300 constituting the actuator device is described in detail. The first electrode 60 constituting the piezoelectric element 300 is cut and separated for each pressure generating chamber 12, and constitutes an individual electrode which is independent for each piezoelectric element 300. The first electrode 60 is formed with a width narrower than the width of the pressure generating chamber 12 in the first direction X of the pressure generating chamber 12. More specifically, in the first direction X of the pressure generating chamber 12, an end portion of the first electrode 60 is located inside a region facing the pressure generating chamber 12. In the second direction Y of the pressure generating chamber 12, both end portions of the first electrode 60 individually extend to the outside of the pressure generating chamber 12. The material of the first electrode 60 is not particularly limited insofar as the material is a metal material. For example, metals, such as Ti, Pt, Ta, Ir, Sr, In, Sn, Au, Al, Fe, Cr, Ni, and Cu, only one kind of these materials, or one obtained by mixing or laminating two or more kinds of these materials may be acceptable as the first electrode 60.

The piezoelectric layer 70 is continuously provided in the first direction X in such a manner that the width in the second direction Y has a predetermined width. The width in the second direction Y of the piezoelectric layer 70 is longer than the length in the second direction Y of the pressure generating chamber 12. Therefore, in the second direction Y of the pressure generating chamber 12, the piezoelectric layer 70 is provided to the outside of the pressure generating chamber 12.

The end portion of the piezoelectric layer 70 on one end in the second direction Y of the pressure generating chamber 12 (the ink supply path side this embodiment) is located on the outer side relative to the end of the first electrode 60. More specifically, the end portion of the first electrode 60 is covered with the piezoelectric layer 70. The end portion of the piezoelectric layer 70 on the other end in the second direction Y of the pressure generating chamber 12 is located on the inner side relative to the end portion of the first electrode 60 (pressure generating chamber 12 side).

To the first electrode 60 which extends to the outside of the piezoelectric layer 70, a lead electrode 90 containing gold (Au) and the like, for example, is connected. Although not illustrated, the lead electrode 90 constitutes a terminal portion to which a connection wiring line which is connected to a drive circuit and the like is to be connected.

Moreover, a concave portion 71 facing each partition 11 is formed in the piezoelectric layer 70. The width in the first direction X of this concave portion 71 is almost equal to or larger than the width in the first direction X of each partition 11. More specifically, the piezoelectric layer 70 is continuously formed over the respective pressure generating chambers 12 along the first direction X, and part of the piezoelectric layer 70 facing each partition 11 is removed to form the concave portion 71. Since the rigidity of a portion facing the end portion in the width direction of the pressure generating chamber 12 of the diaphragm 50 (a so-called arm portion of the diaphragm 50) is suppressed due to the concave portion 71, the piezoelectric element 300 can be favorably displaced.

As the piezoelectric layer 70, a crystal film (perovskite crystal) of the perovskite structure containing a ferroelectric ceramic material which shows the electromechanical transduction action to be formed on the first electrode 60 is mentioned. As the material of the piezoelectric layer 70, a lead-free piezoelectric material which is a perovskite composite oxide which does not contain lead can also be used. Mentioned as the lead-free piezoelectric material are, for example, bismuth ferrite (BiFeO₃, abbreviated as as “BFO”), barium titanate (BaTiO₃, abbreviated as “BT”), sodium potassium niobate (K, Na) (NbO₃, abbreviated as “KNN”), sodium potassium lithium niobate ((K, Na, Li)(NbO₃)), sodium potassium lithium tantalate niobate ((K, Na, Li)(Nb, Ta)O₃), potassium bismuth titanate ((Bi_{1/2}K_{1/2})TiO₃, abbreviated as “BKT”), sodium bismuth titanate ((Bi_{1/2}Na_{1/2})TiO₃, abbreviated as “BNT”), bismuth manganate (BiMnO₃, abbreviated as “BM”), composite oxide having a perovskite structure containing bismuth, potassium, titanium, and iron ((Bi, K)(Ti, Fe)O₃, abbreviated as “BKT-BF”), composite oxide having a perovskite structure containing bismuth, iron, barium and titanium, (Bi, Ba)(Fe, Ti)O₃, abbreviated as “BFO-BT”), those obtained by adding metals, such as manganese, cobalt, and chromium, thereto (Bi, Ba) (Fe, Ti, M)O₃ (M is Mn, Co, or Cr)), and the like.

In this embodiment, BFO is used as the piezoelectric material.

In this embodiment, the piezoelectric layer 70 is patterned by wet and the like as described in detail later. Therefore, the piezoelectric layer 70 of this embodiment is formed in a desired fine shape with ease and in a short time.

The second electrode 80 is continuously provided on the piezoelectric layer 70 in the first direction X of the pressure generating chambers 12 and constitutes a common electrode common to the plurality of piezoelectric elements 300. An end portion of the second electrode 80 on one end in the second direction Y of the pressure generating chamber 12 is located on the outer side relative to the end portion of the piezoelectric layer 70. More specifically, the end portion of the piezoelectric layer 70 is covered with the second electrode 80.

The material of such a second electrode 80 is not particularly limited insofar as the material is a metal material and, for example, the same material as that of the first electrode 60 can be used. The piezoelectric element 300 having such a configuration is displaced by applying a voltage between the first electrode 60 and the second electrode 80. More specifically, by applying a voltage between both the electrodes, piezoelectric distortion arises in the piezoelectric layer 70 provided between the first electrode 60 and the second electrode 80. A portion where the piezoelectric distortion occurs in the piezoelectric layer 70 when a voltage is applied to both the electrodes is referred to as an active portion 320. On the other hand, a portion where the piezoelectric distortion does not arise in the piezoelectric layer 70 is referred to as a non-active portion. In the active portion 320 where the piezoelectric distortion arises in the piezoelectric layer 70, a portion facing the pressure generating chamber 12 is referred to as a flexible portion and a portion outside the pressure generating chamber 12 is referred to as a non-flexible portion.

In this embodiment, all the first electrode 60, the piezoelectric layer 70, and the second electrode 80 are continuously provided to the outside of the pressure generating chamber 12 in the second direction Y of the pressure generating chamber 12. More specifically, the active portion 320 is continuously provided to the outside of the pressure generating chamber 12. Therefore, a portion facing the pressure generating chamber 12 of the piezoelectric element 300 of the active portion 320 serves as a flexible portion and a portion outside the pressure generating chamber 12 serves as a non-flexible portion.

As described above, since the first electrode 60 is cut and separated for each generating chamber 12, a level difference of the first electrode 60 is formed in the piezoelectric element 300 along the second direction Y, i.e., along the longitudinal direction (the second direction Y) of the active portion 320.

As illustrated in FIG. 1 and FIGS. 2A and 2B, onto the flow path formation substrate 10 on which the piezoelectric elements 300 are formed, a protective substrate 30 which protects the piezoelectric elements 300 is bonded with an adhesive 35. The protective substrate 30 is provided with a piezoelectric element holding portion 31 which is a concave portion defines a space which accommodates the piezoelectric element 300. Moreover, the protective substrate 30 is provided with a manifold portion 32 constituting part of a manifold 100. The manifold portion 32 penetrates the protective substrate 30 in the thickness direction and is continuously formed in the width direction of the pressure generating chambers 12 and communicates with the communication portion 15 of the flow path formation substrate 10 as described above. Moreover, the protective substrate 30 is provided with a penetration hole 33 which penetrates the protective substrate 30 in the thickness direction. The lead electrode 90 connected to the first electrode 60 of each piezoelectric element 300 is exposed into the penetration hole 33. To the lead electrode 90 connected to the first electrode 60 of each piezoelectric element 300, one end of the connection wiring line to be connected to a drive circuit, which is not illustrated, is connected within the penetration hole 33.

Onto the protective substrate 30, a compliance substrate 40 containing a sealing film 41 and a stationary plate 42 is bonded. The sealing film 41 contains a material having low rigidity and having flexibility. One surface of the manifold portion 32 is sealed with this sealing film 41. The stationary plate 42 is formed with a hard material, such as metal. Since the region facing the manifold 100 of the stationary plate 42 forms an opening portion 43 where the plate is completely removed in the thickness direction, one surface of the manifold 100 is sealed only with the sealing film 41 having flexibility.

In such an ink jet recording head I of this embodiment, ink is introduced from an ink introduction port connected to an external ink supply unit (not illustrated) to fill the inside of the liquid flow path from the manifold 100 to the nozzle openings 21 with the ink, and then a voltage is applied between each of the first electrode 60 and the second electrode 80 corresponding to each pressure generating chamber 12 according to recording signals from the driving circuit. Thus, the diaphragm 50 is deflected and deformed with the piezoelectric elements 300 to increase the pressure in each pressure generating chamber 12, so that ink droplets are ejected from each nozzle opening 21. Method for manufacturing ink jet recording head

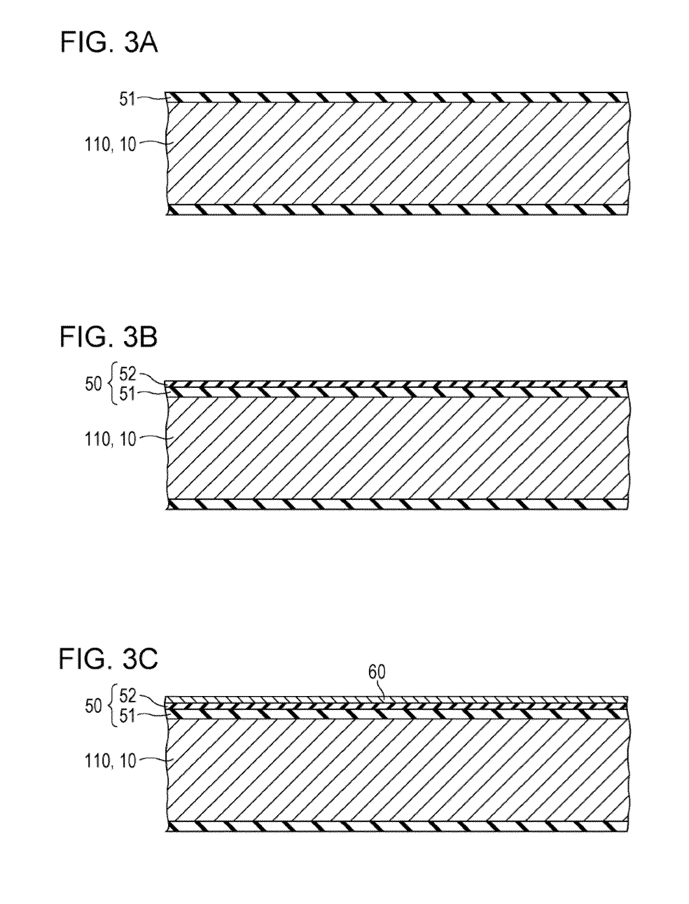

A method for manufacturing such an ink jet recording head of this embodiment is described. FIG. 3A to FIG. 8B are cross-sectional views in the first direction X illustrating the method for manufacturing such the ink jet recording head.

First, as illustrated in FIG. 3A, the elastic film 51 is formed on the surface of a flow path formation substrate wafer 110 which is a silicon wafer. In this embodiment, the elastic film 51 containing silicon dioxide is formed by thermally oxidizing the flow path formation substrate wafer 110. It is a matter of course that a method for forming the elastic film 51 is not limited to the thermal oxidation and the elastic film 51 may be formed by a sputtering method, a CVD method, or the like.

Subsequently, as illustrated in FIG. 3B, the insulator film 52 containing zirconium oxide is formed on the elastic film 51. The insulator film 52 may be formed by molding zirconium by a sputtering method or the like, and then thermally oxidizing the same by heating or may be formed by molding zirconium dioxide by a reactive sputtering method. The diaphragm 50 is formed with the elastic film 51 and the insulator film 52.

Subsequently, as illustrated in FIG. 3C, the first electrode 60 is formed on the entire surface of the insulator film 52. The material of the first electrode 60 is not particularly limited and includes, for example, platinum and iridium. The first electrode 60 can be formed by a sputtering method, a PVD method (physical vapor deposition method), or the like, for example.

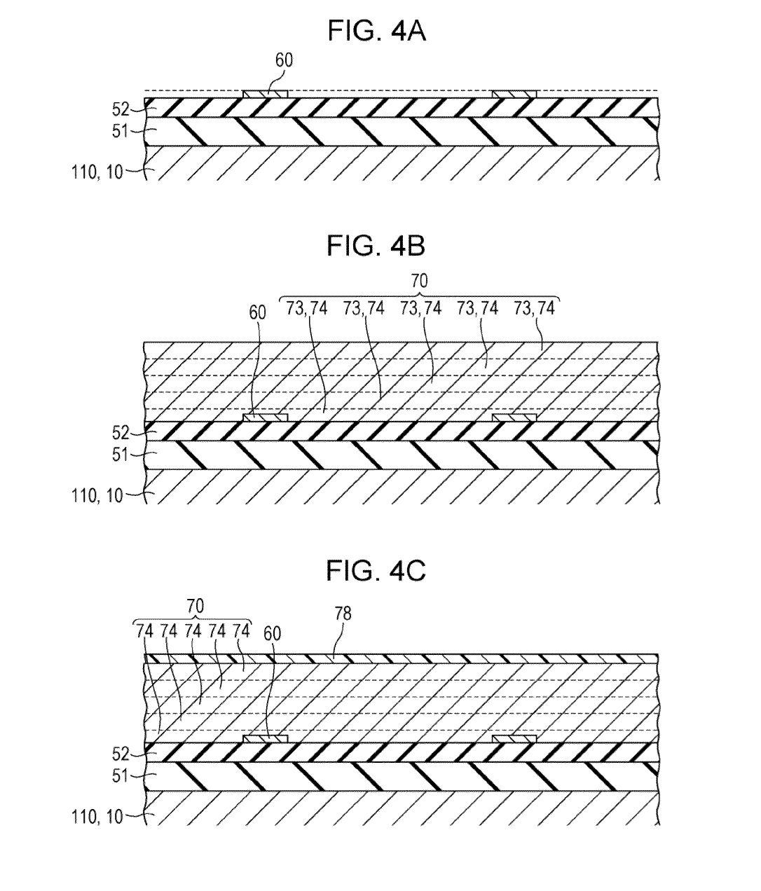

Subsequently, as illustrated in FIG. 4A, the first electrode 60 is patterned. The patterning can be performed by dry etching, such as ion milling, for example.

Next, in this embodiment, a sol or an MOD solution (precursor solution) containing an organic metallic compound, specifically, an organic metallic compound containing Bi, Fe, Mn, Ti, Ba, and the like in a target composition ratio is applied onto the first electrode 60 using a spin coating method or the like to form a piezoelectric precursor film 73 (Application process). A method for manufacturing the piezoelectric layer 70 is not limited to a sol-gel method and an MOD (Metal-Organic Decomposition) method and PVD (Physical Vapor Deposition) methods, such as a sputtering method and a laser ablation method, and the like may be used. More specifically, the piezoelectric layer 70 may be formed by any one of a liquid phase method and a gaseous phase method.

The precursor solution to be applied is one obtained by mixing organic metallic compounds each containing Bi or Fe in such a manner that each metal has a desired molar ratio, and then dissolving or dispersing the mixture using an organic solvent, such as alcohol. As the organic metallic compounds each containing Bi or Fe, metal alkoxide, organic acid salt, β diketone complex, and the like can be used, for example. As the organic metallic compound containing Bi, bismuth 2-ethylhexanoate and the like are mentioned, for example. As the organic metallic compound containing Fe, iron 2-ethyl hexanoate and the like are mentioned, for example. It is a matter of course that an organic metallic compound containing Bi and Fe may be used.

Herein, the formation of the piezoelectric layer 70 containing BFO is described. However, when forming a piezoelectric layer with another piezoelectric material which does not contain lead, the precursor solution may be prepared by mixing organic metallic compounds in such a manner that each metal has a desired molar ratio, and then dissolving or dispersing the mixture using an organic solvent, such as alcohol.

Subsequently, the piezoelectric precursor film 73 is heated to a predetermined temperature (for example, 150 to 200° C.), and is dried for a given period of time (Drying process). Next, the dried piezoelectric precursor film 73 is heated to a predetermined temperature (for example, 350 to 450° C.), and holding the same for a given period of time for degreasing (Degreasing process). The degreasing as used herein refers to separating the organic components contained in the piezoelectric precursor film 73 in the form of NO₂, CO₂, H₂O, and the like, for example. The atmosphere of the drying process and the degreasing process is not limited and the processes may be performed in the atmosphere, in an oxygen environment, or in inactive gas. The application process, the drying process, and the degreasing process may be performed several times.

Next, as illustrated in FIG. 4B, the piezoelectric precursor film 73 is heated and held for a given period of time to be crystallized to thereby form the piezoelectric film 74 (Firing process). The heating temperature may be set to about 600 to 800° C., for example. Also in this firing process, the atmosphere is not limited and the process may be performed in the atmosphere, in an oxygen environment, or in inactive gas.

As a heating device for use in the drying process, the degreasing process, and the firing process, an RTA (Rapid Thermal Annealing) device which performs heating by irradiation with an infrared lamp, a hot plate, and the like are mentioned, for example.

Next, as illustrated in FIG. 4C, a resist film 78 is formed on the piezoelectric layer 70. Herein, the resist film 78 functions as a mask and one containing an organic material is used. As the organic material, a novolac resin obtained by a condensation reaction of phenol or o-, m- or p-cresol, xylenol, or a mixture of these phenol compounds and formaldehyde is preferably used, for example. The novolac resin is suitable as a resist material because highly precise patterning can be achieved.

In this embodiment, the novolac resin is used as the resist film 78. When one which is an organic material is used as the resist film 78, the side etching amount can be more effectively suppressed but a so-called hard mask may be used. By suppressing the side etching amount, the interval of adjacent piezoelectric layers can be narrowed, and resolution enhancement can be realized.

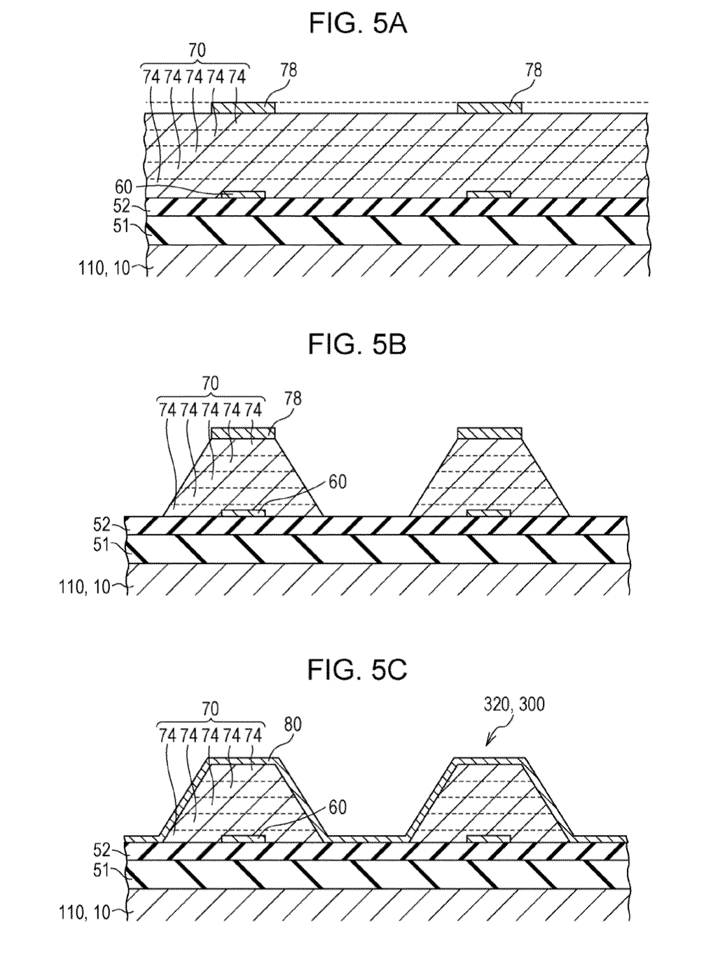

Subsequently, as illustrated in FIG. 5A, patterning is performed by a photolithography method in such a manner that the resist film 78 is formed for each region of the piezoelectric layer 70 in which each piezoelectric element 300 is formed.

Subsequently, as illustrated in FIG. 5B, the piezoelectric layer 70 is patterned by wet etching into a region facing each pressure generating chamber 12 (Patterning process).

As the wet etching solution, hydrochloric acid containing hydrogen chloride in a proportion of 12% by weight is used in this embodiment. By the use of hydrochloric acid, the piezoelectric layer 70 containing BFO can be patterned.

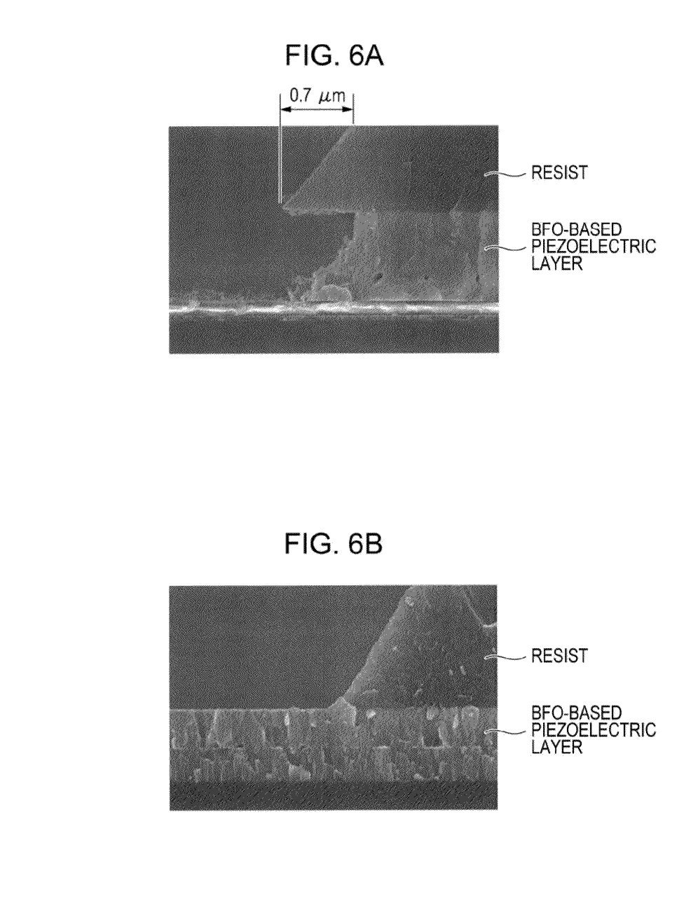

Herein, FIG. 6A shows an SEM photograph taken when wet etching the piezoelectric layer 70 for 120 seconds with hydrochloric acid containing 12% by weight of hydrogen chloride to be used in this embodiment.

As illustrated in FIG. 6A, the BFO piezoelectric layer was patterned by performing wet etching with hydrochloric acid. It was able to be confirmed that the side etching amount was 0.7 μm, which was small.

FIG. 6B shows an SEM photograph taken when performing wet etching with an etching solution (PZT etching solution) for use in etching of a piezoelectric layer containing lead zirconate titanate (PZT). As shown in FIG. 6B, the piezoelectric layer containing a BFO piezoelectric body was not able to be patterned with the etching solution for use in etching of lead zirconate titanate. The PZT etching solution contained hydrogen fluoride (0.01 to 0.90% by weight) and hydrogen chloride (1 to 9% by weight).

Therefore, it was found that the piezoelectric layer containing a BFO piezoelectric body cannot be etched with the etching solution containing hydrogen chloride and hydrogen fluoride and the BFO piezoelectric body can be patterned by the use of hydrochloric acid as in this embodiment.

Herein, one containing hydrogen chloride in a proportion of 12% by weight is mentioned as hydrochloric acid but the hydrochloric acid is not limited thereto. The concentration of the hydrogen chloride in hydrochloric acid is preferably higher than 9% by weight and less than 24% by weight. This is because when the concentration is less than 9% by weight, the etching time to be required is excessively long and when the concentration is higher than 24% by weight, it is difficult to control the etching. Therefore, due to the fact that the concentration is in the range above, the patterning can be performed for an appropriate etching time while controlling the etching.

Next, as illustrated in FIG. 5C, the resist film 78 is removed, and then the second electrode 80 is formed over the piezoelectric layer 70 and the insulator film 52. The second electrode 80 can also be formed by a sputtering method, a PVD method (physical vapor deposition method), an electroless plating method, or the like.

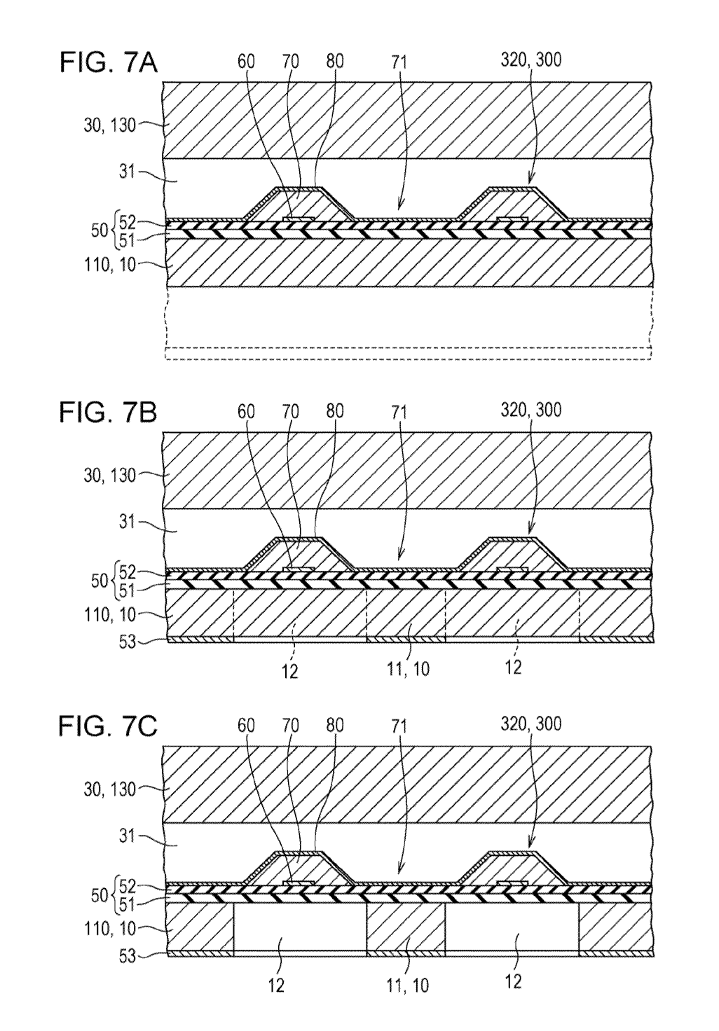

Next, as illustrated in FIG. 7A, a protective substrate wafer 130 which is a silicon wafer and serves as a plurality of protective substrates 30 is bonded with an adhesive to the side of the piezoelectric elements 300 of the flow path formation substrate wafer 110, and then the thickness of the flow path formation substrate wafer 110 is reduced to a predetermined thickness.

Subsequently, as illustrated in FIG. 7B, a mask film 53 is newly formed on the flow path formation substrate wafer 110, and then patterned into a predetermined shape. Then, as illustrated in FIG. 7C, by anisotropically etching (wet etching) the flow path formation substrate wafer 110 using an alkaline solution, such as KOH, through the mask film 53, the pressure generating chamber 12, the ink supply path 13, the communication path 14, the communication portion 15, and the like corresponding to the piezoelectric element 300 are formed.

Thereafter, unnecessary portions of peripheral edge portions of the flow path formation substrate wafer 110 and the protective substrate wafer 130 are removed by cutting by dicing or the like, for example. Then, by bonding the nozzle plate 20 in which the nozzle openings 21 are formed to the surface opposite to the protective substrate wafer 130 of the flow path formation substrate wafer 110 and also bonding the compliance substrate 40 to the protective substrate wafer 130, and then dividing the flow path formation substrate 10 and the like into the flow path formation substrate and the like of one chip size as illustrated in FIG. 1 the wafer 110, the ink jet recording head of this embodiment is obtained.

Thus, in this embodiment, the piezoelectric layer 70 can be easily patterned by wet etching.

In this embodiment, although hydrochloric acid is used as the wet etching solution, the etching solution is not limited thereto. An etching solution containing hydrofluoric acid, for example, buffered fluoric acid, may be used. The content of hydrogen fluoride in the buffered fluoric acid in this case is preferably about 7% by weight, for example. Due to the fact that the content is in the range above, the patterning can be performed for an appropriate etching time while controlling the etching.

### Embodiment 2

Embodiment 2 of the invention is described below. Embodiment 2 is different from Embodiment 1 in that wet etching is performed while dividing the etching into two processes.

More specifically, in this embodiment, a patterning process has a first process of performing wet etching with buffered fluoric acid and a second process of performing wet etching with nitric acid. Thus, by the use of different etching solutions by dividing the patterning process into the two processes, the piezoelectric layer 70 can be more appropriately patterned by wet etching. More specifically, when the wet etching is performed with only buffered fluoric acid, the piezoelectric layer 70 itself is patterned but a reaction product (residual substance) and the like generated due to the etching cannot be sufficiently removed, so that a large number of reaction products adhere in some cases.

Therefore, in this embodiment, the reaction product generated due to the etching is removed by further performing wet etching with nitric acid in the second process, whereby the piezoelectric layer 70 is patterned by these two processes.

In this case, by further adjusting the etching time in the first process, the taper angle of the piezoelectric layer 70, i.e., the inclination of the end portion, can be adjusted. Specifically, by prolonging the time of the wet etching with buffered fluoric acid in the first process, the inclination of the etching surface of the piezoelectric layer 70 can be made gentle.

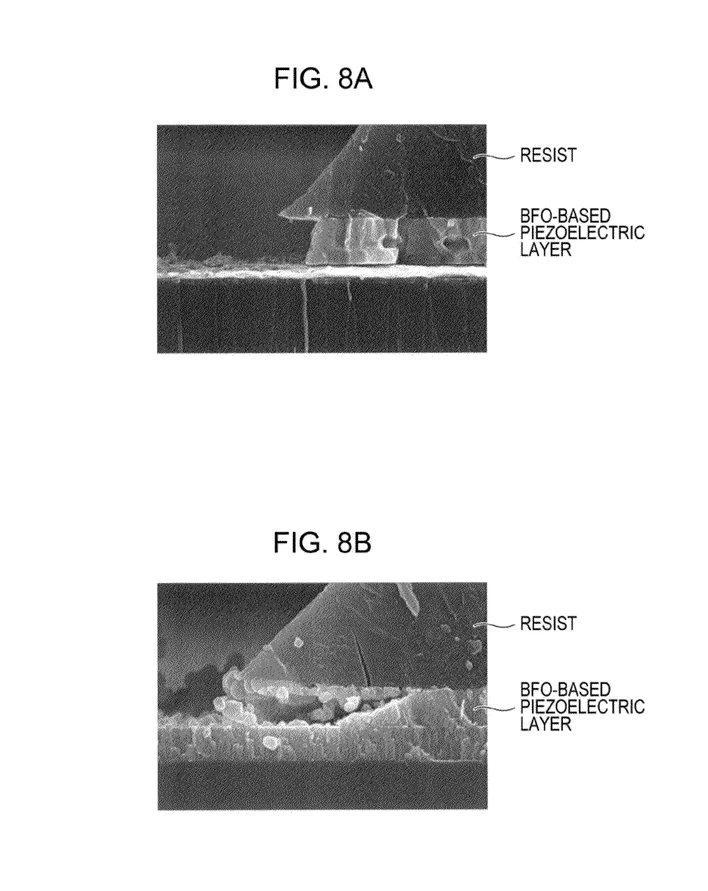

This respect is described in detail with reference to FIGS. 8A and 8B.

FIG. 8A shows an SEM photograph taken when etching the piezoelectric layer 70 with buffered fluoric acid with a concentration of 20% by weight (Product Name: SE-13, manufactured by Stella Chemifa Corp.) for 75 seconds as the first process, and then etching the piezoelectric layer 70 with nitric acid as the second process. As shown in FIG. 8A, the etched surface has less reaction products produced by the etching, and the piezoelectric layer 70 is substantially patterned.

FIG. 8B shows an SEM photograph taken when etching the piezoelectric layer 70 with buffered fluoric acid with a concentration of 20% by weight for 180 seconds. Thus, when etched with buffered fluoric acid with a concentration of 20% by weight only in the first process, the piezoelectric layer 70 itself is etched but a reaction product produced by the etching adheres. Then, it is configured in this embodiment so that the piezoelectric layer 70 can be substantially patterned as shown in FIG. 8A by removing the reaction product by performing etching with nitric acid as the second process.

As is understood from the comparison between FIG. 8A and FIG. 8B, the inclination of an end portion of the piezoelectric layer is altered by changing the etching time. More specifically, even when the same etching solution is used, the inclination is more gentle in the case shown in FIG. 8B in which the etching time is long than in the case shown in FIG. 8A.

Thus, by prolonging the etching time in the first process, the taper (end portion of the piezoelectric layer) of the piezoelectric layer 70 can be formed with a desired angle when the second process is completed. In this case, when the taper angle of the piezoelectric layer 70 is gentle, the second electrode 80 is more likely to adhere to the piezoelectric layer 70. When the taper angle of the piezoelectric layer 70 is steep, the piezoelectric elements 300 can be arranged with high density. Therefore, a desired structure can be easily formed by changing the etching time according to the desired property.

In this embodiment, the etching solution used in the second process is nitric acid but the same effects can be obtained even when the etching solution is hydrochloric acid.

In the first process, hydrochloric acid is used as the etching solution. In the case of hydrochloric acid, altering the inclination of the end portion of the piezoelectric layer as described in this embodiment cannot be achieved. However, since some reaction products adhere due to the etching also in the case of hydrochloric acid, it is preferable that the reaction product is removed with nitric acid in the second process. When using hydrochloric acid in the first process, the etching solution for use in the second process is limited to nitric acid. This is because it is preferable to use different etching solutions in the first process and in the second process.

### Ink Jet Recording Apparatus

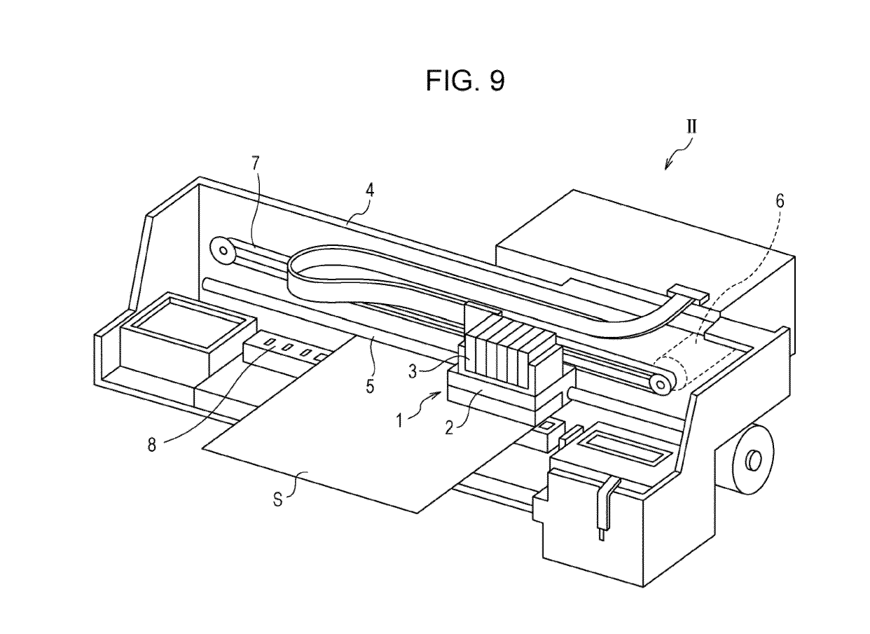

The ink jet recording head I according to any one of the above-described embodiments is mounted on an ink jet recording apparatus II, for example, as illustrated in FIG. 9. To a recording head unit 1 having the ink jet recording head I, a cartridge 2 constituting an ink supply unit is removably attached. A carriage 3 carrying the recording head unit 1 is provided to a carriage shaft 5 attached to an apparatus body 4 in such a manner as to be movable in the axial direction. The recording head unit 1 ejects a black ink composition and a color ink composition, for example.

The driving force of a driving motor 6 is transmitted to the carriage 3 through a plurality of gears, which are not illustrated, and a timing belt 7, whereby the carriage 3 carrying the recording head unit 1 is moved along the carriage shaft 5. On the other hand, the apparatus body 4 is provided with a platen 8 along the carriage shaft 5. It is configured so that a recording sheet S which is a recording medium, such as paper, which is fed by a feed roller and the like, which are not illustrated, is wound around the platen 8, and then transported.

Then, in an aspect of the invention, the equalization of the ejection characteristics can be achieved while suppressing the breakage of the piezoelectric elements 300 constituting the ink jet recording head I as described above. As a result, the ink jet recording apparatus II in which the printing quality is improved and the durability is increased can be realized.

In the example described above, one in which the ink jet recording head I is mounted on the carriage 3 and moves in the main scanning direction is mentioned as an example of the ink jet recording apparatus II but the configuration thereof is not particularly limited thereto. The ink jet recording apparatus II may be a so-called line-type recording apparatus which performs printing by fixing the ink jet recording head I, and then moving the recording sheets S, such as paper, in the sub-scanning direction may be acceptable, for example.

### Ultrasonic Transducer

Furthermore, the method for manufacturing the piezoelectric element and the ink jet recording head described above can also be applied to a method for manufacturing an ultrasonic transducer. Hereinafter, an ultrasonic transducer and an ultrasonic device carrying the ultrasonic transducer are described. An embodiment described below does not unduly limit the contents of the invention described in Claims and all the configurations described in this embodiment are not necessarily indispensable as the means for solving the problems of the invention. The same members as those in the above-described embodiments are designated by the same reference numerals and the duplicated description is omitted.

In this embodiment, ultrasonic waves are transmitted and received using an electroacoustic transduces utilizing the piezoelectric effect. The electroacoustic transducer is a piezoelectric element and utilizes the conversion from electric energy to mechanical energy when transmitting ultrasonic waves (converse piezoelectric effect) and the change due to the contraction and the elongation of the piezoelectric layer excites the diaphragm in such a manner as to vibrate to thereby transmit ultrasonic waves. Therefore, in this case, the piezoelectric element is a transmitting ultrasonic transducer.

In order to receive ultrasonic waves reflected from a target detector, mechanical energy is converted to electric energy (direct piezoelectric effect), the electric energy is generated by the deformation of the piezoelectric layer, and then signals of the electric energy are detected. Therefore, in this case, the piezoelectric element is a receiving ultrasonic transducer.

The piezoelectric element in this embodiment has the first electrode provided on the diaphragm, the piezoelectric layer provided on the first electrode, and the second electrode provided on the piezoelectric layer.

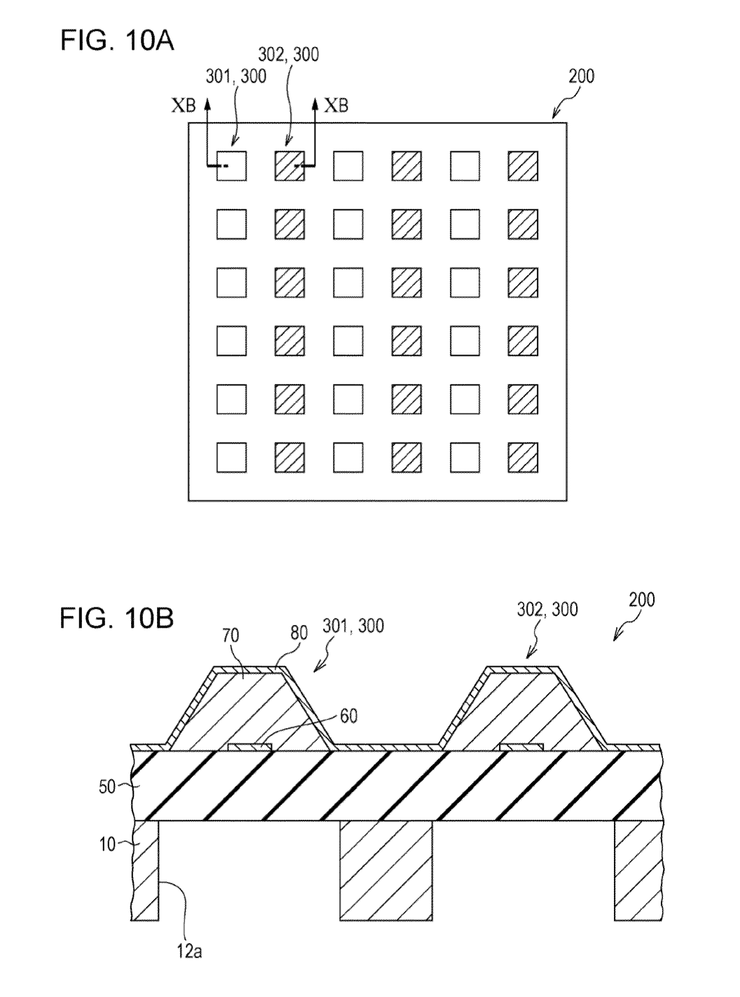

FIGS. 10A and 10B are a plan view of an ultrasonic device carrying ultrasonic transducers and a cross sectional view thereof along the XB-XB line, respectively.

As illustrated in FIG. 10A, a plurality of transmitting ultrasonic transducers 301 and receiving ultrasonic transducers 302 are provided in the shape of an array on the substrate 10 having substrate openings 12a to form an ultrasonic device 200 (array sensor). The plurality of transmitting ultrasonic transducers 301 and the plurality of receiving ultrasonic transducers 302 are alternately disposed for each row and the energization is switched for each sequence of the transducers. According to such switching of the energization, line scanning and sector scanning are realized. The levels of the output and the input of ultrasonic waves are determined according to the number and the number of sequences of the transducers to be energized. In the drawing, the illustration is omitted and the transducers of 6 lines x 6 rows are illustrated. The number of lines and the number of rows of the arrangement are determined according to the extension of the scanning range.

The transmitting ultrasonic transducers 301 and the receiving ultrasonic transducers 302 can be alternately arranged for each transducer type. In this case, by setting the ultrasonic wave transmitting and receiving sources in which the central axis of the transmitting side and the central axis of the receiving side are aligned, the directional angle of the transmission and the directional angle of the reception are easily aligned.

In this example, both the transmitting ultrasonic transducers 301 and the receiving ultrasonic transducers 302 are arranged on one substrate 10 in order to reduce the size of a device. However, according to the function of the ultrasonic transducers, the transmitting ultrasonic transducers 301 and the receiving ultrasonic transducer 302 can be individually arranged on separate substrates or a plurality of substrates can be used according to the intended use. Furthermore, it is also possible to impart both the transmitting and receiving functions to one ultrasonic transducer utilizing the time lag between the transmission and the reception.

In FIG. 10B, as Examples usable as an ultrasonic transducer, the substrate 10 is constituted by a single crystal silicon having (100), (110), or (111) orientation, for example. Or, in addition to the silicon material, a ceramic material typified by ZrO₂ or Al₂O₃, glass ceramic materials, oxide substrate materials, such as MgO and LaAlO₃, and inorganic materials, such as SiC, SiO₂, polycrystalline silicon, and Si₃N₄ can also be used. Or, laminated materials obtained by combining the materials may be acceptable.

The diaphragm 50 is formed on the substrate 10 (piezoelectric layer 70 side). The film thickness of the diaphragm 50 is determined based on the resonance frequency.

The substrate openings 12a are formed in the substrate 10. The substrate openings 12a can be formed using processing methods, such as etching, polishing, and laser processing, according to substrate materials.

The diaphragm 50, the first electrode 60, the piezoelectric layer 70, and the second electrode 80 are the same as those of Embodiment 1 described above, and therefore the description of the configurations is omitted. The ultrasonic device is required to be driven in a higher frequency region as compared with the case of a liquid ejecting head typified by the ink jet recording head I. Therefore, the configurations of the piezoelectric layer 70, the diaphragm 50, each electrode material, and the substrate 10, and the physical property values, such as the thickness and the Young's modulus, may be adjusted.

Also in this embodiment, the piezoelectric layer 70 contains a perovskite oxide which does not contain lead similarly as in Embodiment 1. The piezoelectric layer 70 is also formed by a process of forming a piezoelectric film, and a patterning process of providing a resist on the piezoelectric film, and then performing patterning by wet etching with an etching solution containing either hydrochloric acid or hydrofluoric acid similarly as in Embodiment 1. The patterning process may be divided into two processes as in Embodiment 2. More specifically, a transmitting ultrasonic transducer 301 and a receiving ultrasonic transducer 302 of this embodiment can be formed in the same manner as in Embodiment 1 or 2. Due to the fact that the transmitting ultrasonic transducer 301 and the receiving ultrasonic transducer 302 of this embodiment are formed in the same manner as in Embodiment 1 or 2, the over etching of the diaphragm 50 constituting the transmitting ultrasonic transducer 301 and the receiving ultrasonic transducer 302 of this embodiment is suppressed. Therefore, the variation in the thickness of the diaphragm 50 is suppressed, so that the transmission performance and the receiving performance of the ultrasonic device improve.

Furthermore, a wiring line (not illustrated) is connected to each of the transmitting ultrasonic transducers 301 and the receiving ultrasonic transducers 302 and each wiring line is connected to a terminal portion (not illustrated) of a control substrate (not illustrated) through a flexible printed circuit substrate (not illustrated). The control substrate is provided with a control portion (not illustrated) containing an operation portion, a storage portion, and the like. The control portion is configured to control input signals to be input into the transmitting ultrasonic transducers 301 and also treat output signals to be output from the receiving ultrasonic transducers 302.

Thus, since the piezoelectric elements 300 produced using the MEMS technique can be disposed with a narrower pitch (high resolution) in the ultrasonic device of this application as compared with a sensor utilizing a bulk type piezoelectric ceramics and the like, effects of reducing the size, reducing the thickness, and saving the energy of a device and an apparatus carrying the device are obtained. Moreover, since manufacturing variation between the piezoelectric elements 300 hardly arises, an effect of increasing the recognition accuracy is also obtained.

Furthermore, by reducing the film thickness of the piezoelectric layer 70, an effect of increasing the displacement properties to thereby improve the efficiency of the transmission and the reception of ultrasonic waves is obtained.

### Other Embodiments

As described above, one embodiment of the invention is described but the basic configuration of the invention is not limited to the configuration described above.

In the embodiments described above, the description of the invention is directed to the case where the ink jet recording head is taken as an example of the liquid ejecting head. However, the embodiments of the invention is widely directed to general liquid ejecting heads. Examples of liquid ejecting heads include, for example, various kinds of recording heads for use in image recording devices, such as a printer, color material ejecting heads for use in manufacturing of color filters of liquid crystal displays and the like, electrode material ejecting heads for use in formation of electrodes of an organic EL display, FED (field emission display), and the like, and bioorganic material ejecting heads for use in manufacturing of bio chips.

Furthermore, an aspect of the invention can be applied to not only such liquid ejecting heads (ink jet recording heads) but actuator devices to be mounted on various kinds of apparatuses. The actuator device employing the piezoelectric element manufactured according to an aspect of the invention can also be applied to various kinds of sensors, such as an ultrasonic sensor and a pyroelectric sensor, for example.

In Embodiments 1 and 2, the second electrode is a common electrode but an aspect of the invention is not limited thereto. The first electrode may be used as a common electrode and the second electrode may be used as an individual electrode. In this case, when a protective film covering the piezoelectric layer and the second electrode is provided, the adhesiveness of the protective film improves because the surface of an end portion of the piezoelectric layer 70 is roughened by patterning the piezoelectric film by wet etching.

The entire disclosure of Japanese Patent Application No. 2013-060904, filed Mar. 22, 2013 is expressly incorporated by reference herein.

What is claimed is:

1. A method for manufacturing a liquid ejecting head having a flow path formation substrate that is provided with a liquid flow path communicating with a nozzle opening for discharging liquid and a piezoelectric element that is provided on the flow path formation substrate and applies pressure to the liquid flow path, the method comprising:
forming a piezoelectric film for the piezoelectric element containing a perovskite oxide which does not contain lead; and
patterning the piezoelectric film by applying a resist on the piezoelectric film and wet etching the piezoelectric film with an etching solution containing either hydrochloric acid or hydrofluoric acid.

2. The method for manufacturing a liquid ejecting head according to claim 1, wherein
the patterning includes a first etching with an etching solution containing either hydrochloric acid or hydrofluoric acid and a second etching with an etching solution containing hydrochloric acid or nitric acid and being different from that of the first etching.

3. The method for manufacturing a liquid ejecting head according to claim 2, wherein the second etching is performed after performing the first etching.

4. The method for manufacturing a liquid ejecting head according to claim 3, wherein
the etching solution in the first etching contains hydrofluoric acid, and
a taper angle of the piezoelectric element is controlled by adjusting a wet etching time in the first etching.

5. The method for manufacturing a liquid ejecting head according to claim 1, wherein
the perovskite oxide which does not contain lead is bismuth ferrite.

6. The method for manufacturing a liquid ejecting head according to claim 1, wherein
the resist contains novolac resin.

7. A method for manufacturing a piezoelectric element that has a piezoelectric film containing a perovskite oxide which does not contain lead and has a first electrode and a second electrode provided on respective surfaces of the piezoelectric film, the method comprising:
forming the piezoelectric film, and
patterning the piezoelectric film by applying a resist on the piezoelectric film and wet etching the piezoelectric film with an etching solution containing either hydrochloric acid or hydrofluoric acid.

8. A method for patterning a piezoelectric film, comprising:
applying a resist on a piezoelectric film containing a perovskite oxide which does not contain lead, and
wet etching the piezoelectric film with an etching solution containing either hydrochloric acid or hydrofluoric acid.

9. A method for manufacturing an ultrasonic transducer that has a piezoelectric film containing a perovskite oxide which does not contain lead and has a first electrode and a second electrode provided on respective surfaces of the piezoelectric film, the method comprising:
forming the piezoelectric film, and
patterning the piezoelectric film by applying a resist on the piezoelectric film and wet etching the piezoelectric film with an etching solution containing either hydrochloric acid or hydrofluoric acid.
